(19) United States
(12) Patent Application Publication
(10) Pub. No.: US 2024/0405122 A1
(43) Pub. Date: Dec. 5, 2024

(54) SEMICONDUCTOR DEVICE

(71) Applicant: FUJI ELECTRIC CO., LTD., Kanagawa (JP)

(72) Inventors: Yosuke SAKURAI, Azumino-city (JP); Seiji NOGUCHI, Matsumoto-city (JP); Tatsuya NAITO, Matsumoto-city (JP); Nao SUGANUMA, Matsumoto-city (JP); Takuya YAMADA, Matsumoto-city (JP); Masaaki FURUKAWA, Matsumoto-city (JP); Ryutaro HAMASAKI, Matsumoto-city (JP)

(21) Appl. No.: 18/641,403

(22) Filed: Apr. 21, 2024

(30) Foreign Application Priority Data
Jun. 5, 2023 (JP) 2023-092627

(51) Int. Cl. H01L 29/78; H01L 23/64; H01L 29/08

(52) U.S. Cl. CPC H01L 29/7813; H01L 23/645; H01L 29/086

(57) ABSTRACT

A semiconductor device including an active portion is provided, the semiconductor device comprising: a drift region of a first conductivity type provided in the semiconductor substrate; a base region of a second conductivity type provided above the drift region; a gate pad provided above the semiconductor substrate; an emitter electrode provided above the semiconductor substrate; a gate trench portion provided on a front surface of the semiconductor substrate in the active portion; and a gate wiring portion for connecting the gate pad and the gate trench portion; wherein the gate wiring portion has: a first gate trench wiring portion which extends in a predetermined direction; and a second gate trench wiring portion which extends in a different direction from the first gate trench wiring portion and intersects the first gate trench wiring portion at an intersection portion; and the emitter electrode is provided above the intersection portion.

### BACKGROUND

### 1. Technical Field

The present invention relates to a semiconductor device.

### 2. Related Art

Patent document 1 describes “a semiconductor device which can improve the electrical performance”.

### PRIOR ART DOCUMENT

### Patent Document

Patent Document 1: Japanese Patent Application Publication No. 2020-136315
Patent Document 2: Japanese Patent Application Publication No. 2019-091892
Patent Document 3: Japanese Patent Application Publication No. 2017-103400

### BRIEF DESCRIPTION OF THE DRAWINGS

FIG. 1A shows an example of an upper surface of a semiconductor device 100.

FIG. 1B shows an example of an enlarged view of a region R in FIG. 1A.

FIG. 1C shows an example of a cross section a-a′ in FIG. 1B.

FIG. 1D shows an example of a cross section b-b′ in FIG. 1B.

FIG. 1E shows an example of a cross section c-c′ in FIG. 1B.

FIG. 1F shows an example of a cross section d-d′ in FIG. 1B.

FIG. 2 shows an example of a diagram in which a trench bottom region 60 is projected to the upper surface of the region R in FIG. 1A.

FIG. 3 shows an example of an enlarged view of a region R in a variation of the semiconductor device 100.

FIG. 4A shows an example of a diagram in which the trench bottom region 60 is projected to the upper surface of the region R in a variation of the semiconductor device 100.

FIG. 4B shows an example of the cross section d-d′ in a variation of the semiconductor device 100.

FIG. 5 shows an example of the cross section d-d′ in a variation of the semiconductor device 100.

FIG. 6A shows an example of an enlarged view of the region R in a variation of the semiconductor device 100.

FIG. 6B shows an example of the cross section d-d′ in a variation of the semiconductor device 100.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a gravitational direction or to a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of an N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to an acceptor concentration set as a negative ion concentration, taking into account of polarities of charges. As an example, when the donor concentration is ND and the acceptor concentration is NA, the net doping concentration at any position is given as Np-NA. In the present specification, the net doping concentration may be simply referred to as the doping concentration.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be defined as the concentration of the donor, acceptor or net doping.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

The present specification employs SI unit system. In the present specification, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E−16 indicates 1×10⁻¹⁶.

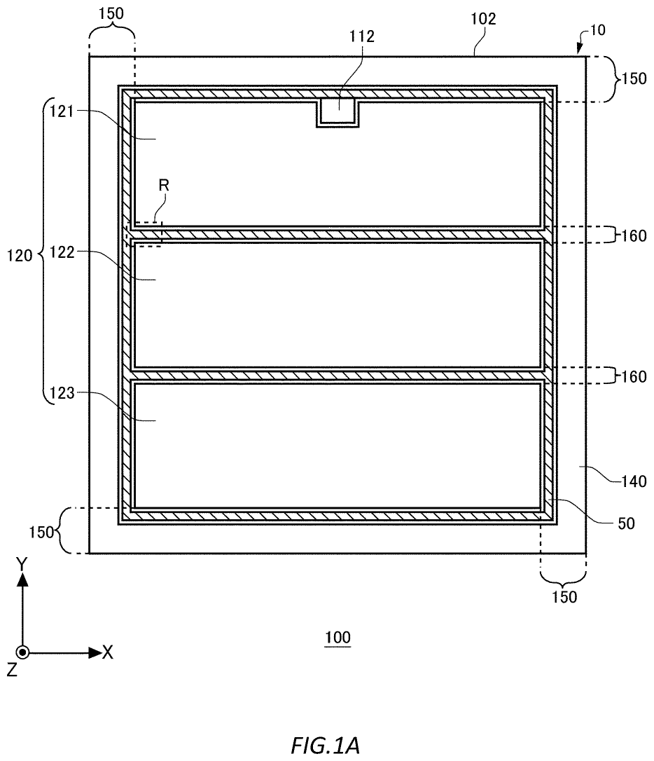

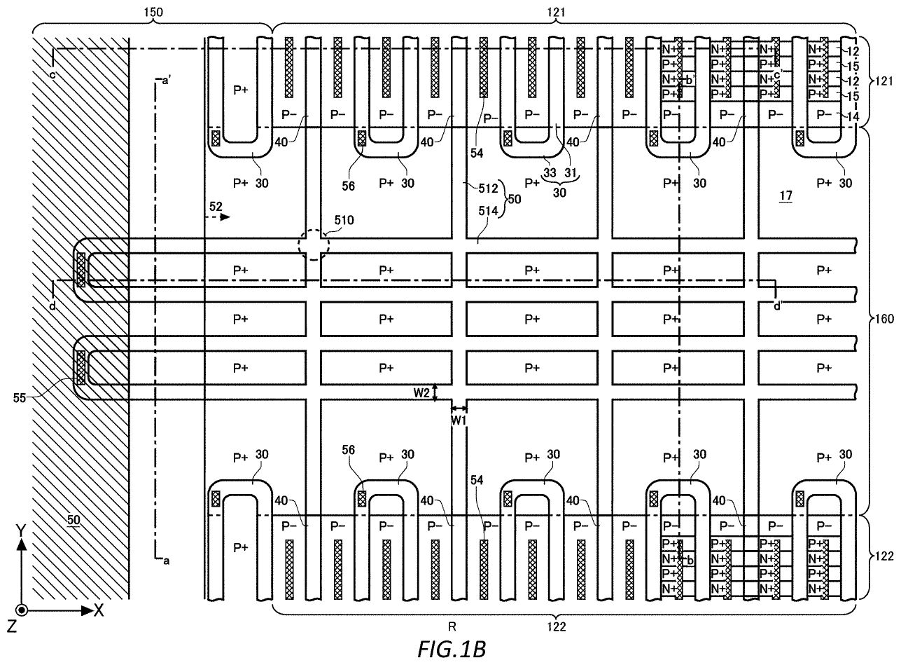

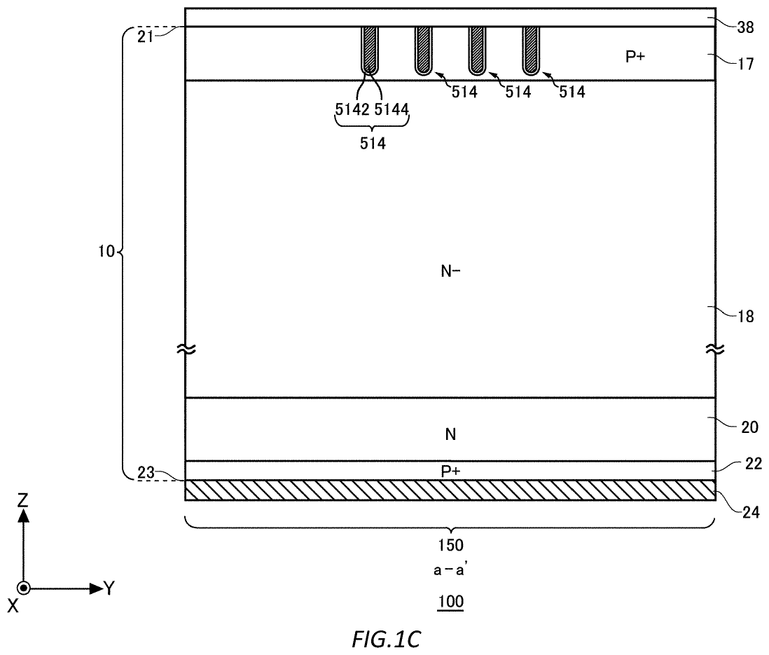

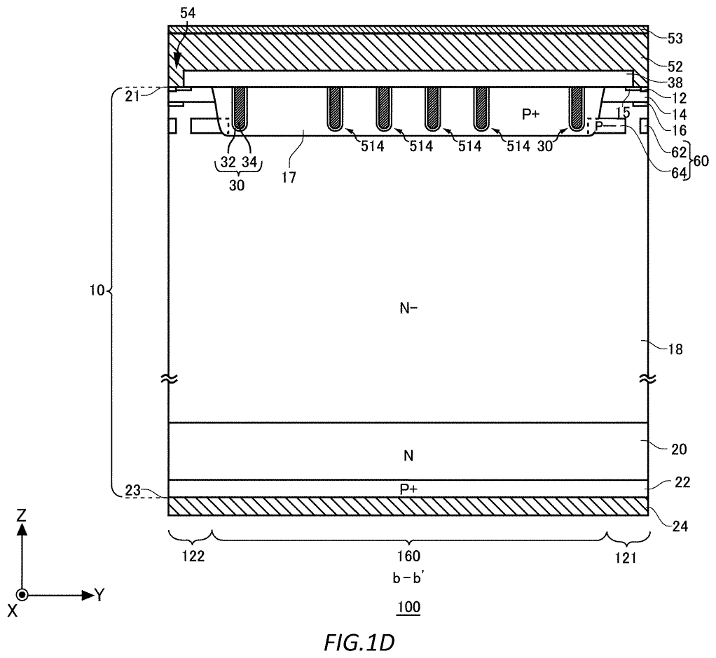

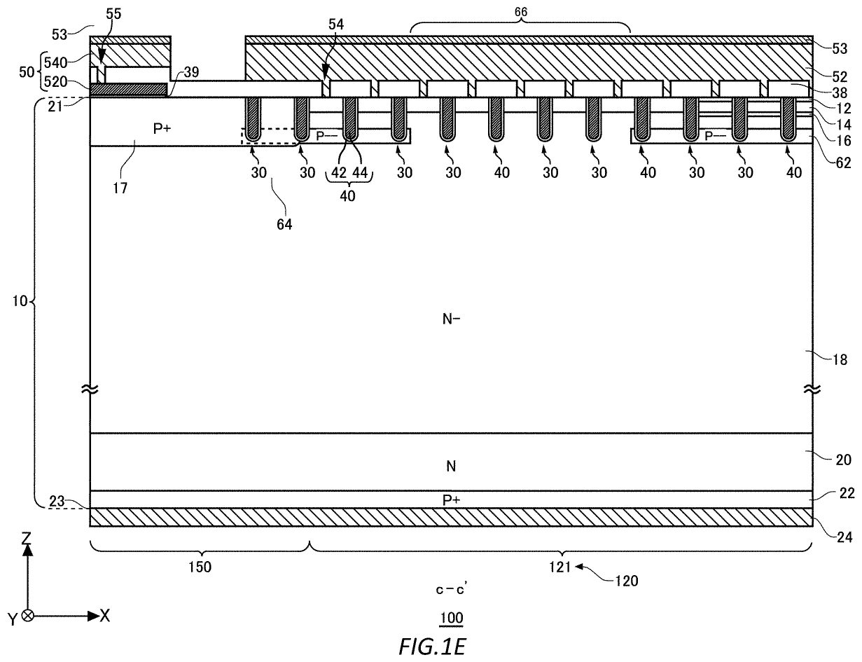

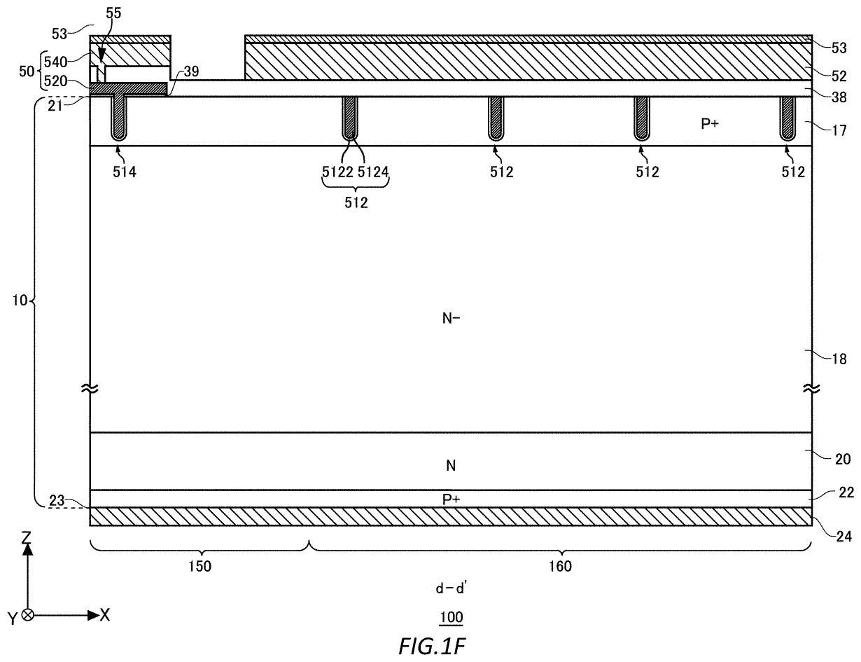

FIG. 1A shows an example of an upper surface of a semiconductor device 100. The semiconductor device 100 in this example includes a gate wiring portion 50, a gate pad 112, an active portion 120, an edge termination structure portion 140, an outer peripheral portion 150, and a transversal portion 160.

The semiconductor substrate 10 is a substrate that is formed of a semiconductor material. The semiconductor substrate 10 may be a silicon substrate or may be a silicon carbide substrate. The semiconductor substrate 10 in this example is the silicon substrate. It is to be noted that when simply referred to as a top view in the present specification, it means that the upper surface side of the semiconductor substrate 10 is viewed from above. The semiconductor substrate 10 has an end side 102. In addition, the semiconductor substrate 10 has a front surface 21 and a back surface 23 as described below.

The active portion 120 is a region in which the principal current flows in the depth direction between the front surface 21 and the back surface 23 of the semiconductor substrate 10 when the semiconductor device 100 operates. An emitter electrode 52 is provided above the active portion 120, but is omitted in this diagram.

The active portion 120 may have a first active region 121, a second active region 122, and a third active region 123. The number of the active region which the active portion 120 has is not limited to this. The active portion 120 may have at least two active regions, or may have four or more active regions. The first active region 121 and the second active region 122 may be provided to be separated from each other. The second active region 122 and the third active region 123 may be provided to be separated from each other. Similarly, when the active portion 120 has four or more active regions, each active region may be provided to be separated from each other. Although the active regions in this example are provided to be separated from each other in the Y axis direction, a plurality of active regions may be provided to be separated from each other in the X axis direction.

The transversal portion 160 is a region between a plurality of active regions provided to be separated from each other. In other words, the transversal portion 160 may separate the first active region 121 and the second active region 122 from each other, and may separate the second active region 122 and the third active region 123 from each other. Although the transversal portion 160 in this example is a region which extends in the X axis direction, it may be a region which extends in the Y axis direction.

The outer peripheral portion 150 is a region between the active portion 120 and the end side 102. In other words, the outer peripheral portion 150 may be a region which surrounds the first active region 121, the second active region 122, the third active region 123, and the transversal portion 160.

The gate pad 112 is provided above the semiconductor substrate 10. A gate potential is applied to the gate pad 112. The gate pad 112 is electrically connected to a gate trench portion 40 of the active portion 120. The gate trench portion 40 is described below.

In a top view, the gate wiring portion 50 is provided in the outer peripheral portion 150 and the transversal portion 160. The gate wiring portion 50 connects the gate pad 112 to the gate trench portion 40. The gate wiring portion 50 being provided in the transversal portion 160 can reduce the variation of the wiring length from the gate pad 112 for each region of the semiconductor substrate 10. The gate wiring portion 50 provided in the outer peripheral portion 150 may have a different configuration from that of the gate wiring portion 50 provided in the transversal portion 160, or may have the same configuration. The configuration of the gate wiring portion 50 is described below.

An edge termination structure portion 140 is provided at the front surface 21 of the semiconductor substrate 10. In a top view, the edge termination structure portion 140 is provided in the outer peripheral portion 150. The edge termination structure portion 140 relaxes an electric field strength in the front surface 21 side of the semiconductor substrate 10. The edge termination structure portion 140 may include at least one of a guard ring, a field plate, or a RESURF which is annularly provided to enclose the active portion 120.

FIG. 1B shows an example of an enlarged view of the region R in FIG. 1A. The semiconductor device 100 of this example includes a dummy trench portion 30, a gate trench portion 40, a gate wiring portion 50, an emitter region 12, a base region 14, a contact region 15, and a well region 17 on the front surface 21 of the semiconductor substrate 10. In addition, the semiconductor device 100 of this example includes an emitter electrode 52 provided above the front surface 21 of the semiconductor substrate 10.

The dummy trench portion 30 is provided on the front surface 21 of the semiconductor substrate 10 in the active portion 120. The dummy trench portion 30 is a trench portion that is electrically connected to the emitter electrode 52. The dummy trench portions 30 are arrayed at a predetermined interval along a predetermined array direction (the X axis direction in this example). The dummy trench portion 30 may have two extending portions 31 extending along the extending direction (the Y axis direction in this example) which is parallel to the front surface 21 of the semiconductor substrate 10 and is perpendicular to the array direction, and the connecting portion 33 which connects the two extending portions 31.

At least part of the connecting portion 33 is preferably formed in a curved shape. The end portions of two extending portions 31 of the dummy trench portion 30 can be connected to relax the electric field strength at the end portion of the extending portion 31.

The gate trench portion 40 is provided on the front surface 21 of the semiconductor substrate 10 in the active portion 120. The gate trench portion 40 is provided to extend in a predetermined extending direction (the Y axis direction in this example). The gate trench portions 40 are arrayed at predetermined intervals along a predetermined array direction (the X axis direction in this example). Although the gate trench portion 40 in this example has an I-shape in the front surface 21 of the semiconductor substrate 10, it may have a U-shape in the front surface 21 of the semiconductor substrate 10. In other words, the gate trench portion 40 may have two extending portions which extend along the extending direction and a connecting portion which connects the two extending portions.

The semiconductor device 100 in this example has a structure in which one gate trench portions 40 and two dummy trench portions 30 are repeatedly arrayed. In other words, the semiconductor device 100 in this example has the gate trench portions 40 and the dummy trench portions 30 at a ratio of 1:2. For example, the semiconductor device 100 has the gate trench portions 40 of the I-shape and the dummy trench portions 30 of the U-shape in an alternate manner.

However, the ratio of the gate trench portion 40 and the dummy trench portion 30 is not limited to this example. The ratio of the gate trench portion 40 may be higher than the ratio of the dummy trench portion 30, or the ratio of the dummy trench portion 30 may be the same as the ratio of the gate trench portion 40. The ratio of the gate trench portions 40 and the dummy trench portions 30 may be 1:1 or may be 3:2. In addition, the semiconductor device 100 may have the trench portions which are entirely the gate trench portions 40, without any dummy trench portion 30.

The base region 14 is a region of a second conductivity type provided above the drift region 18 described below. The base region 14 is of the P-type as an example.

The emitter region 12 is a region of the first conductivity type which has a higher doping concentration than the drift region 18 and is provided above the drift region 18. The emitter region 12 in this example is of the N+ type as an example. Examples of a dopant of the emitter region 12 include arsenic (As). On the front surface 21, the emitter region 12 is provided in contact with the gate trench portion 40. The emitter region 12 may be provided to extend in the X axis direction from one of the two trench portions to the other. The emitter region 12 is also provided below the contact hole 54.

In addition, the emitter region 12 may or may not be in contact with the dummy trench portion 30. The emitter region 12 in this example is in contact with the dummy trench portion 30.

The contact region 15 is a region of a second conductivity type, which is provided above the base region 14 and has a higher doping concentration than the base region 14. The contact region 15 in this example is of the P+ type as an example. The contact region 15 in this example is provided on the front surface 21. The contact region 15 may be provided in the X axis direction from one of two trench portions to the other. The contact region 15 may or may not be in contact with the gate trench portion 40 or the dummy trench portion 30. The contact region 15 in this example is in contact with the dummy trench portion 30 and the gate trench portion 40. The contact region 15 is also provided below the contact hole 54.

The well region 17 is a region of the second conductivity type provided above the drift region 18. The well region 17 is of the P+ type as an example. A diffusion depth of the well region 17 may be deeper than depths of the gate trench portion 40 and the dummy trench portion 30. The boundary between the well region 17 and the base region 14 in the X axis direction may be the boundary between the outer peripheral portion 150 and the active portion 120. The boundary between the well region 17 and the base region 14 in the Y axis direction may be the boundary between the transversal portion 160 and the active portion 120.

The emitter electrode 52 is provided above the semiconductor substrate 10 with the interlayer dielectric film 38 interpolated between them. The interlayer dielectric film 38 is omitted in FIG. 1B. A contact hole 54, a contact hole 55, and a contact hole 56 are provided to penetrate through the interlayer dielectric film 38. The emitter electrode 52 is provided above the gate trench portion 40, the dummy trench portion 30, the emitter region 12, the base region 14, the contact region 15, and the well region 17. In addition, the emitter electrode 52 is provided above the gate wiring portion 50 provided on the transversal portion 160. The emitter electrode 52 and the gate wiring portion 50 are insulated from each other.

The emitter electrode 52 is formed of a material including a metal. At least a partial region of the emitter electrode 52 may be formed of metal such as aluminum (Al) or of a metal alloy such as an aluminum-silicon alloy (AlSi) or an aluminum-silicon-copper alloy (AlSiCu). The emitter electrode 52 may have a barrier metal layer formed of titanium or titanium compound and the like in the lower layer of a region formed of aluminum and the like.

In the active portion 120, the contact hole 54 is formed above each region of the emitter region 12 and the contact region 15. The contact hole 54 may be formed above the base region 14. The contact hole 54 is not provided above the well region 17 provided at both ends of the Y axis direction. In this manner, one or more contact holes 54 are formed in the interlayer dielectric film 38. The one or more contact holes 54 may be provided to extend in the extending direction.

The contact hole 55 connects the gate metal layer 540 of the gate wiring portion 50 to the gate conductive portion within the second gate trench wiring portion 514. The gate metal layer 540 is described below. A plug layer formed of tungsten or the like may be formed inside the contact hole 55.

The contact hole 56 connects the emitter electrode 52 with a dummy conductive portion inside the dummy trench portion 30. A plug layer formed of tungsten or the like may be formed inside the contact hole 56.

The gate wiring portion 50 has a first gate trench wiring portion 512 and a second gate trench wiring portion 514.

The first gate trench wiring portion 512 extends in a predetermined direction. The first gate trench wiring portion 512 in this example is provided to extend in the Y axis direction. The first gate trench wiring portion 512 may be provided to extend from the first active region 121 to the second active region 122. The first gate trench wiring portion 512 may connect the gate trench portion 40 of the first active region 121 to the gate trench portion 40 of the second active region 122. In other words, the gate trench portion 40 and the first gate trench wiring portion 512 may be electrically connected to each other.

The first gate trench wiring portion 512 and the gate trench portion 40 may have the same configuration. In other words, the width of the first gate trench wiring portion 512 and the width of the gate trench portion 40 may be the same, and the depth of the first gate trench wiring portion 512 and the depth of the gate trench portion 40 may be the same. However, the width of the first gate trench wiring portion 512 and the width of the gate trench portion 40 may be different and the depth of the first gate trench wiring portion 512 and the depth of the gate trench portion 40 may be different. The first gate trench wiring portion 512 and the gate trench portion 40 may be integrally formed in the same process. However, the first gate trench wiring portion 512 and the gate trench portion 40 may be formed in different processes. The boundary between the first gate trench wiring portion 512 and the gate trench portion 40 may be the boundary between the active portion 120 and the transversal portion 160.

The first gate trench wiring portion 512 may include a plurality of first gate trench wiring portions 512. The number of the plurality of first gate trench wiring portions 512 may be the same as the number of the plurality of gate trench portions 40 of the active portion 120. In other words, the first gate trench wiring portion 512 may connect all the gate trench portion 40 provided in the first active region 121 and the gate trench portion 40 provided in the second active region 122 to each other. However, the number of the plurality of first gate trench wiring portions 512 may be different from the number of the plurality of gate trench portions 40 of the active portion 120, and parts of the plurality of gate trench portions 40 provided in the plurality of active regions may not be connected to each other across a plurality of active regions.

The second gate trench wiring portion 514 may extend in a direction which is different from that of the first gate trench wiring portion 512 and intersect the first gate trench wiring portion 512 at the intersection portion 510. The second gate trench wiring portion 514 in this example extends in the X axis direction which is different from the Y axis direction which is the extending direction of the first gate trench wiring portion 512. The first gate trench wiring portion 512 and the second gate trench wiring portion 514 may be electrically connected at the intersection portion 510.

The intersection portion 510 may be provided inside the well region 17 in the cross section parallel to the depth direction of the semiconductor substrate 10 and may have the lower end which is shallower than the lower end of the well region 17. In other words, the diffusion depth of the well region 17 may be deeper than the depth of the first gate trench wiring portion 512 and the second gate trench wiring portion 514 and may be deeper than the depth of the intersection portion 510. The intersection portion 510 being provided inside the well region 17 can relax the electric field strength in the bottom portion of the intersection portion 510. In this way, the decrease in withstand voltage of the semiconductor device 100 can be suppressed.

The second gate trench wiring portion 514 may include a plurality of second gate trench wiring portions 514. The second gate trench wiring portion 514 in this example includes four second gate trench wiring portions 514. The second gate trench wiring portion 514 in this example has a U-shape. In other words, the second gate trench wiring portion 514 may have two extending portions which extend along the extending direction (the X axis direction in this example) which is parallel to the front surface 21 of the semiconductor substrate 10 and is perpendicular to the array direction, and a connecting portion which connects the two extending portions. The second gate trench wiring portion 514 may also have a similar U-shape in the end portion in the +X axis direction. In other words, the second gate trench wiring portion 514 may have a loop shape.

The plurality of second gate trench wiring portions 514 may each have intersection portions 510 with the first gate trench wiring portion 512. Each of the plurality of second gate trench wiring portions 514 in this example has four intersection portions 510 in the illustrated region R. The number of the intersection portions 510 that each of the plurality of second gate trench wiring portions 514 has may be the same as the number of the plurality of first gate trench wiring portions 512.

The well region 17 may be provided to extend from one end of the second gate trench wiring portion 514 provided in the outer peripheral portion 150 of the semiconductor device 100 to the other end of the second gate trench wiring portion 514 provided in the outer peripheral portion 150. In other words, all the intersection portions 510 at which the plurality of first gate trench wiring portions 512 and the plurality of second gate trench wiring portions 514 intersect may be provided inside the well region 17.

The width W1 of the first gate trench wiring portion 512 and the width W2 of the second gate trench wiring portion 514 may be the same. In this way, the first gate trench wiring portion 512 and the second gate trench wiring portion 514 can be formed in the same process. However, the width W1 of the first gate trench wiring portion 512 and the width W2 of the second gate trench wiring portion 514 may be different and the first gate trench wiring portion 512 and the second gate trench wiring portion 514 may be formed in different processes.

The gate wiring portion 50 in this example has the first gate trench wiring portion 512 and the second gate trench wiring portion 514 in the transversal portion 160. In this way, polysilicon does not need to be left above the semiconductor substrate 10 in the manufacturing process of the semiconductor device 100, which allows the planarization of the semiconductor device 100 and can also improve the patterning precision in a large diameter wafer. The first gate trench wiring portion 512 and the second gate trench wiring portion 514 having trench structures can reduce the resistance value of the gate wiring portion 50 in comparison to the case when the gate runner structures with the same width are provided above the semiconductor substrate 10. In addition, polysilicon does not need to be left above the semiconductor substrate 10 in the manufacturing process of the semiconductor device 100, which allows entire surface etchback and can reduce the number of masks.

The emitter electrode 52 may be provided above the intersection portion 510. In other words, in a top view, the emitter electrode 52 may be provided from the first active region 121 to the second active region 122 over the second gate trench wiring portion 514.

FIG. 1B shows an example of the enlarged view of the region R in FIG. 1A. The region R is a region including the first active region 121, the second active region 122, the transversal portion 160, and the outer peripheral portion 150 which is positioned in the −X axis direction of the active portion 120. The region including the second active region 122, the third active region 123, the transversal portion 160, and the outer peripheral portion 150 positioned in the −X axis direction of the active portion 120 may also have a configuration similar to that of the region R. The region including the first active region 121, the second active region 122, the transversal portion 160, the outer peripheral portion 150 positioned in the +X axis direction of the active portion 120 may also have a similar configuration which has reflection symmetry with the region R. The region including the second active region 122, the third active region 123, the transversal portion 160, and the outer peripheral portion 150 positioned in the +X axis direction of the active portion 120 may also have a similar configuration which has reflection symmetry with the region R.

For example, in any region, the gate wiring portion 50 may have the first gate trench wiring portion 512 and the second gate trench wiring portion 514, and may intersect the first gate trench wiring portion 512 and the second gate trench wiring portion 514 at the intersection portion 510. The first gate trench wiring portion 512 may connect the gate trench portion 40 of the first active region 121 to the gate trench portion 40 of the second active region 122 and may connect the gate trench portion 40 of the second active region 122 to the gate trench portion 40 of the third active region 123. In any region, the emitter electrode 52 may be provided above the intersection portion 510. In other words, the emitter electrode 52 may be provided as a single electrode across a plurality of active regions without being divided by the gate wiring portion 50.

The emitter electrode 52 being provided above the intersection portion 510 can reduce the parasitic inductance of the semiconductor device 100 in comparison to the case when the emitter electrode 52 is provided to be divided by the gate wiring portion 50. Reducing the parasitic inductance can suppress the oscillation generated upon the turning on and short-circuit of the semiconductor device 100.

FIG. 1C shows an example of the cross section a-a′ in FIG. 1B. The cross section a-a′ is the Y-Z plane which passes the well region 17 in the outer peripheral portion 150. The semiconductor device 100 in this example has the semiconductor substrate 10, the interlayer dielectric film 38, and the collector electrode 24 in the cross section a-a′.

The drift region 18 is a region of the first conductivity type which is provided in the semiconductor substrate 10. The drift region 18 in this example is of the N-type as an example. The drift region 18 may be a region which has remained without other doping regions formed in the semiconductor substrate 10. In other words, the doping concentration of the drift region 18 may be the doping concentration of the semiconductor substrate 10.

A buffer region 20 is a region of the first conductivity type which is provided on a back surface 23 side of the semiconductor substrate 10 relative to the drift region 18. The buffer region 20 in this example is of the N type as an example. The doping concentration in the buffer region 20 is higher than the doping concentration in the drift region 18. The buffer region 20 may function as a field stop layer which prevents a depletion layer extending from the lower surface side of the base regions 14 from reaching the collector region 22 of the second conductivity type. It is to be noted that the buffer region 20 may be omitted.

The collector region 22 is provided below the buffer region 20. The collector region 22 has the second conductivity type. The collector region 22 in this example is of the P+ type as an example.

The collector electrode 24 is formed at the back surface 23 of the semiconductor substrate 10. The collector electrode 24 is formed of a conductive material such as metal. The material of the collector electrode 24 may be the same as or different from the material of the emitter electrode 52.

The second gate trench wiring portion 514 has the gate trench, the gate dielectric film 5142, and the gate conductive portion 5144 formed on the front surface 21. The gate dielectric film 5142 is formed to cover an inner wall of the gate trench. The gate dielectric film 5142 may be formed by oxidizing or nitriding a semiconductor on the inner wall of the gate trench. The gate conductive portion 5144 is formed farther inward than the gate dielectric film 5142 inside the gate trench. The gate dielectric film 5142 insulates the gate conductive portion 5144 from the semiconductor substrate 10. The gate conductive portion 5144 is formed of a conductive material such as polysilicon. The second gate trench wiring portion 514 may be covered by the interlayer dielectric film 38 in the front surface 21.

The second gate trench wiring portion 514 may be provided inside the well region 17. In other words, in the depth direction of the semiconductor substrate 10, the depth of the well region 17 may be deeper than the depth of the second gate trench wiring portion 514.

The interlayer dielectric film 38 is provided above the semiconductor substrate 10. The interlayer dielectric film 38 of this example is provided in contact with the front surface 21. A film thickness of the interlayer dielectric film 38 is, for example, 1.0 μm, but is not limited to this. The interlayer dielectric film 38 may be silicon oxide film. The interlayer dielectric film 38 may be a BPSG (Boro-phospho Silicate Glass) film, may be a BSG (borosilicate glass) film, or may be a PSG (Phosphosilicate glass) film. The interlayer dielectric film 38 may also include a high temperature silicon oxide (HTO: High Temperature Oxide) film.

FIG. 1D shows an example of the cross section b-b′ in FIG. 1B. The cross section b-b′ is the cross section which passes the first active region 121, the transversal portion 160, and the second active region 122, and is in the Y-Z plane which passes the contact hole 54 in the active portion 120. The semiconductor device 100 in this example has a semiconductor substrate 10, an interlayer dielectric film 38, an emitter electrode 52, a plated film 53, and a collector electrode 24 in the cross section b-b′. The emitter electrode 52 and the plated film 53 are formed above the semiconductor substrate 10 and the interlayer dielectric film 38. The semiconductor device 100 in this example may include an accumulation region 16. The accumulation region 16 is described below.

The trench bottom region 60 is a region of the second conductivity type. The trench bottom region 60 in this example is of a P−− type as an example. The doping concentration of the trench bottom region 60 may be lower than the doping concentration of the base region 14. The trench bottom region 60 may be connected to the well region 17.

The trench bottom region 60 may have a first trench bottom portion 62 and a second trench bottom region 64. The second trench bottom region 64 may be provided to be separated from the first trench bottom portion 62 and connected to the well region 17.

The dummy trench portion 30 may have the same structure as the second gate trench wiring portion 514. The dummy trench portion 30 has a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The emitter electrode 52 is provided above the interlayer dielectric film 38. The emitter electrode 52 and the second gate trench wiring portion 514 are insulated by the interlayer dielectric film 38 from each other. The interlayer dielectric film 38 is provided with one or more contact holes 54 for electrically connecting the emitter electrode 52 to the semiconductor substrate 10. The contact hole 56 may be similarly provided to penetrate the interlayer dielectric film 38.

The plated film 53 is formed above the emitter electrode 52. The plated film 53 is formed of a conductive material such as metal. The material of the plated film 53 may include at least one of gold, palladium, or nickel. The plated film 53 may also be formed below the collector electrode 24. The plated film 53 being formed above the emitter electrode 52 can improve the contact property with bonding wire and lead frame and the like via solder and the like and ensure an electrical connection with external devices.

The plated film 53 may be formed above the emitter electrode 52 over the entire emitter electrode 52. As described above, the emitter electrode 52 may be provided from the first active region 121 to the second active region 122 over the second gate trench wiring portion 514. Therefore, above the intersection portion 510, the semiconductor device 100 may include the plated film 53 provided on the emitter electrode 52.

FIG. 1E shows an example of the cross section c-c′ in FIG. 1B. The cross section c-c′ is the cross section which passes the first active region 121 and the outer peripheral portion 150, and is in the X-Z plane which passes the emitter region 12 in the active portion 120.

An accumulation region 16 is a region of the first conductivity type which is provided on the front surface 21 side of the semiconductor substrate 10 relative to the drift region 18. The accumulation region 16 in this example is of the N+ type as an example. However, the accumulation region 16 may not be provided. The doping concentration of the accumulation region 16 may be higher than the doping concentration of the drift region 18. An ion implantation dose amount of the accumulation region 16 may be 1.0 E+12 cm⁻² or more and 3.0 E+13 cm⁻² or less. The accumulation region 16 being provided can enhance a carrier injection enhancement effect (IE effect) to decrease an ON voltage of the semiconductor device 100.

The gate trench portion 40 may have the same structure as the second gate trench wiring portion 514 and the dummy trench portion 30. The gate trench portion 40 has the gate trench, the gate dielectric film 42, and the gate conductive portion 44 which are formed on the side of the front surface 21. The gate dielectric film 42 is formed to cover an inner wall of the gate trench. The gate conductive portion 44 is formed inside the gate trench and is formed farther inward than the gate dielectric film 42. The gate dielectric film 42 insulates the gate conductive portion 44 from the semiconductor substrate 10. The gate trench portion 40 may be covered with the interlayer dielectric film 38 in the front surface 21.

The trench bottom region 60 is provided in contact with the bottom portion of the gate trench portion 40. The trench bottom region 60 may be provided in contact with the bottom portion of the dummy trench portion 30. The trench bottom region 60 in this example is provided in contact with the bottom portion of the gate trench portion 40 and the dummy trench portion 30.

The trench bottom region 60 in this example is provided to extend from the lower end of one trench portion among a plurality of trench portions to the lower end of opposing another trench portion in the trench array direction of the plurality of trench portions. The trench bottom region 60 may be provided to extend from the lower end of one trench portion among the plurality of trench portions beyond the lower end of the opposing another trench portion to the lower end of the trench portion in direct contact with the opposing another trench portion. In other words, the trench bottom region 60 may be provided to extend beyond the lower end of two or more trench portions.

The trench bottom region 60 being provided in contact with the bottom portion of the gate trench portion 40 can suppress the potential rise around the gate trench portion 40 upon the turning on of the semiconductor device 100 and can suppress the dV/dt of the semiconductor device 100. In this way, the generation of the noise according to the switching operation of the semiconductor device 100 can be reduced.

The trench bottom region 60 has the first trench bottom portion 62 and the second trench bottom region 64 which is provided to be separated from the first trench bottom portion 62 and is connected to the well region 17 as described above. In other words, the active portion 120 may have the trench bottomless region 66 in which the trench bottom region 60 is not provided. The trench bottomless region 66 being provided can reduce the electronic barrier and reduce on-loss Eon. Upon the turning on of the semiconductor device 100, the implantation of electrons may first start in the trench bottomless region 66 and subsequently the electric conduction may start in the active portion 120 in which the trench bottom region 60 is provided.

The emitter region 12 is provided above the first trench bottom portion 62. The emitter region 12 may not be provided above the second trench bottom region 64 and in the trench bottomless region 66. The emitter region 12 not being provided in the trench bottomless region 66 facilitates the trench bottomless region 66 to operate as a trigger at the time for starting electric conduction.

The base region 14 may be provided above the trench bottom region 60 and in the trench bottomless region 66. The base region 14 being provided in the trench bottomless region 66 allows the trench bottomless region 66 to operate as a trigger at the time for starting electric conduction.

The accumulation region 16 may be provided above the trench bottomless region 66 and in the trench bottomless region 66. The accumulation region 16 in this example is provided only above the first trench bottom portion 62.

The gate wiring portion 50 has the gate runner 520 and the gate metal layer 540. The gate runner 520 and the gate metal layer 540 are connected via the contact hole 55 provided in the interlayer dielectric film 38. Similar to the contact hole 54 and the contact hole 56, the contact hole 55 may be provided to penetrate the interlayer dielectric film 38.

The gate runner 520 is provided in the outer peripheral portion 150 of the semiconductor device 100. The gate runner 520 is provided above the semiconductor substrate 10 with the oxide film 39 interpolated between them. The gate runner 520 may be formed of the conductive material such as polysilicon. The gate runner 520 in this example is formed of polysilicon.

The oxide film 39 may be formed through oxidation or nitriding of the semiconductor of the semiconductor substrate 10. The oxide film 39 may be formed in the same process as the insulating film provided within a trench. However, the oxide film 39 may be formed in a different process from that of the insulating film provided within the trench. The oxide film 39 insulates the gate runner 520 and the semiconductor substrate 10.

The gate metal layer 540 is provided in the outer peripheral portion 150 of the semiconductor device 100. The gate metal layer 540 is provided above the semiconductor substrate 10 with the interlayer dielectric film 38 interpolated between them. The gate metal layer 540 is formed of a material containing metal. The material of the gate metal layer 540 may be the same as or different from the material of the emitter electrode 52.

The gate metal layer 540 and the emitter electrode 52 are provided to be separated from each other. In this way, the emitter electrode 52 and the gate wiring portion 50 are insulated from each other.

The plated film 53 may be provided above the gate metal layer 540. However, the plated film 53 may not be provided above the gate metal layer 540.

FIG. 1F shows an example of the cross section d-d′ in FIG. 1B. The cross section d-d′ is the cross section which passes the outer peripheral portion 150 and the transversal portion 160 and is in the X-Z plane which passes the first gate trench wiring portion 512 in the transversal portion 160.

The first gate trench wiring portion 512 may have the same structure as the second gate trench wiring portion 514, the dummy trench portion 30, and the gate trench portion 40. The first gate trench wiring portion 512 has the gate trench, the gate dielectric film 5122, and the gate conductive portion 5124 formed on the side of the front surface 21. The gate dielectric film 5122 is formed to cover an inner wall of the gate trench. The gate conductive portion 5124 is formed inside the gate trench and is formed farther inward than the gate dielectric film 5122. The gate dielectric film 5122 insulates the gate conductive portion 5124 from the semiconductor substrate 10. The first gate trench wiring portion 512 may be covered with the interlayer dielectric film 38 in the front surface 21.

The first gate trench wiring portion 512 may be provided inside the well region 17. In other words, the depth of the well region 17 may be deeper than the depth of the first gate trench wiring portion 512.

The depth of the second gate trench wiring portion 514 may be the same as the depth of the first gate trench wiring portion 512, may be deeper than the depth of the first gate trench wiring portion 512, and may be shallower than the depth of the first gate trench wiring portion 512. The depth of the second gate trench wiring portion 514 in this example is the same as the depth of the first gate trench wiring portion 512.

The gate runner 520 may be connected to the end portion of the second gate trench wiring portion 514 in the outer peripheral portion 150. The gate metal layer 540 may be connected to the end portion of the second gate trench wiring portion 514 via the gate runner 520 in the outer peripheral portion. In other words, the gate conductive portion 5144 of the second gate trench wiring portion 514, the gate runner 520, and the gate metal layer 540 may be electrically connected to each other.

In the semiconductor device 100 in this example, the gate pad 112 is electrically connected to the gate metal layer 540 and the gate runner 520 provided in the outer peripheral portion 150 of the semiconductor device 100. The gate metal layer 540 and the gate runner 520 are electrically connected to the second gate trench wiring portion 514 in the outer peripheral portion 150. The second gate trench wiring portion 514 is electrically connected to the first gate trench wiring portion 512 in the intersection portion 510. The first gate trench wiring portion 512 is electrically connected to the gate trench portion 40 of the active portion 120. In this manner, the gate pad 112 is electrically connected to the gate trench portion 40 of the active portion 120.

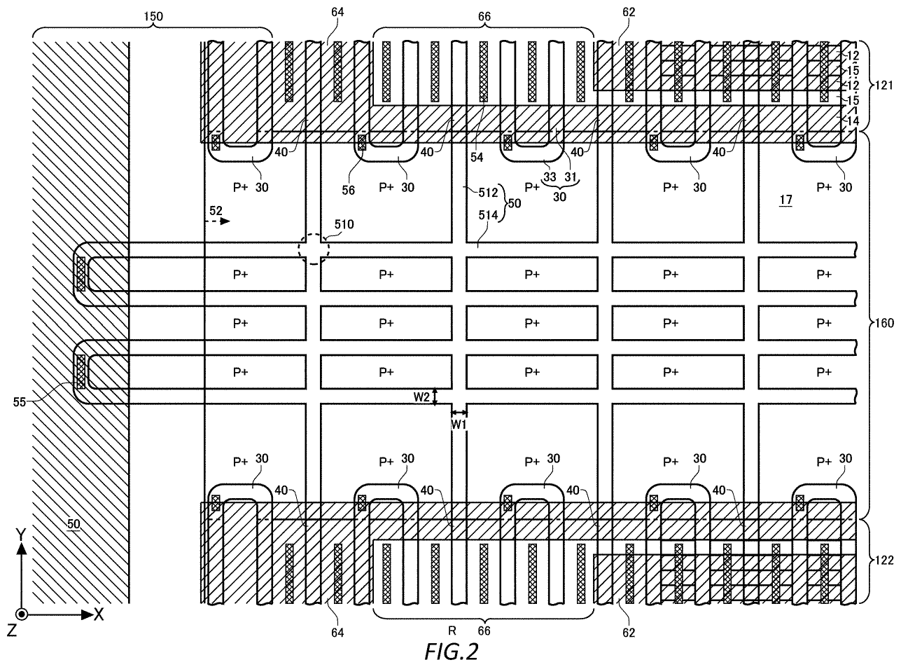

FIG. 2 shows an example of a diagram in which the trench bottom region 60 is projected to the upper surface of the region R in FIG. 1A. The trench bottom region 60 in this example has the first trench bottom portion 62 and the second trench bottom region 64 which is provided to be separated from the first trench bottom portion 62 and is connected to the well region 17. The active portion 120 in this example has the trench bottomless region 66 in which the trench bottom region 60 is not provided.

In a top view, the first trench bottom portion 62 may be provided inside the active portion 120. In other words, in a top view, the first trench bottom portion 62 may be provided inside the first active region 121, the second active region 122, and the third active region 123. The trench bottomless region 66 or the second trench bottom region 64 may be provided in the region in which the first trench bottom portion 62 is not provided among the active portion 120.

The second trench bottom region 64 is provided outside the first trench bottom portion 62 and is separated from the first trench bottom portion 62. The second trench bottom region 64 may be provided from the active portion 120 to the transversal portion 160. In other words, in a top view, the second trench bottom region 64 may be provided to overlap with the first active region 121 and the transversal portion 160, and may be provided to overlap with the second active region 122 and the transversal portion 160, and may be provided to overlap with the third active region 123 and the transversal portion 160.

The second trench bottom region 64 may be provided from the active portion 120 to the outer peripheral portion 150. In other words, in a top view, the second trench bottom region 64 may be provided to overlap with the first active region 121 and the outer peripheral portion 150, and may be provided to overlap with the second active region 122 and the outer peripheral portion 150, and may be provided to overlap with the third active region 123 and the outer peripheral portion 150.

The emitter region 12 may be provided above the first trench bottom portion 62. The emitter region 12 may not be provided above the second trench bottom region 64 and in the trench bottomless region 66. The emitter region 12 not being provided in the trench bottomless region 66 can facilitate the trench bottomless region 66 to operate as a trigger at the time for starting electric conduction.

The base region 14 may be provided above the trench bottom region 60 and in the trench bottomless region 66. The base region 14 being provided in the trench bottomless region 66 allows the trench bottomless region 66 to operate as a trigger at the time for starting electric conduction.

The second trench bottom region 64 may be provided beyond the dummy trench portion 30 which is closest to the outer peripheral portion 150. However, the second trench bottom region 64 only needs to be provided to connect to the well region 17, and may be provided farther inward than the dummy trench portion 30 which is closest to the outer peripheral portion 150.

The trench bottomless region 66 in this example is provided near the outer peripheral portion 150 and the transversal portion 160. The trench bottomless region 66 may be provided near the center of the active portion 120 and is separated from the outer peripheral portion 150 and the transversal portion 160. In this case, the emitter region 12 may not be provided in the trench bottomless region 66. In addition, in the trench bottomless region 66, the gate trench portion 40 may not be provided and only the dummy trench portion 30 may be provided.

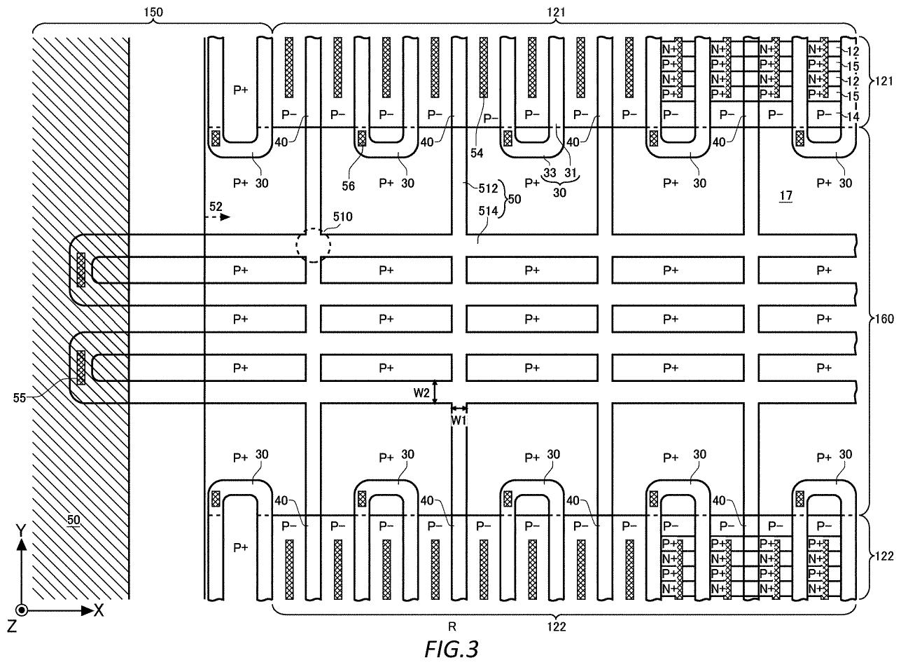

FIG. 3 shows an example of an enlarged view of the region R in a variation of the semiconductor device 100. The semiconductor device 100 in this example differs from the example in FIG. 1F in that the width W1 of the first gate trench wiring portion 512 is different from the width W2 of the second gate trench wiring portion 514. This example describes points that differ from the example shown in FIG. 1F in particular, and other points may be the same as those of the example shown in FIG. 1F.

The width W2 of the second gate trench wiring portion 514 may be wider than the width W1 of the first gate trench wiring portion 512. The width W2 of the second gate trench wiring portion 514 being wider than the width W1 of the first gate trench wiring portion 512 can increase the cross section area of the gate conductive portion 5144 and can reduce the resistance value. However, the width W2 of the second gate trench wiring portion 514 may be the same as the width W1 of the first gate trench wiring portion 512 and may be narrower than the width W1 of the first gate trench wiring portion 512.

As an example, when the width W2 of the second gate trench wiring portion 514 is narrower than the width W1 of the first gate trench wiring portion 512, the number of the plurality of second gate trench wiring portions 514 provided in the transversal portion 160 may be increased. In this way, the total cross section area of the gate conductive portion 5144 in the plurality of second gate trench wiring portions 514 can be increased and the resistance value can be reduced.

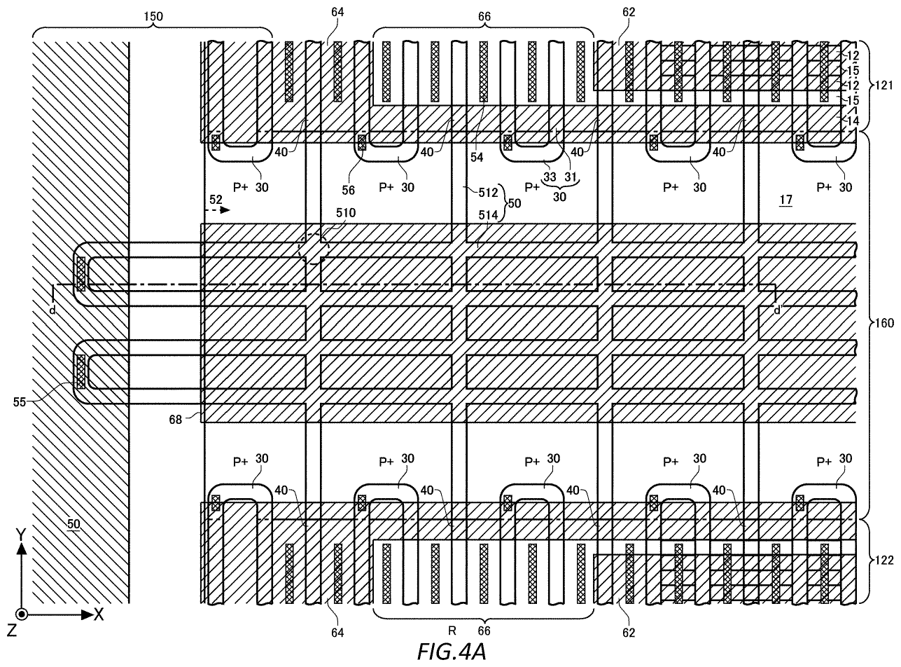

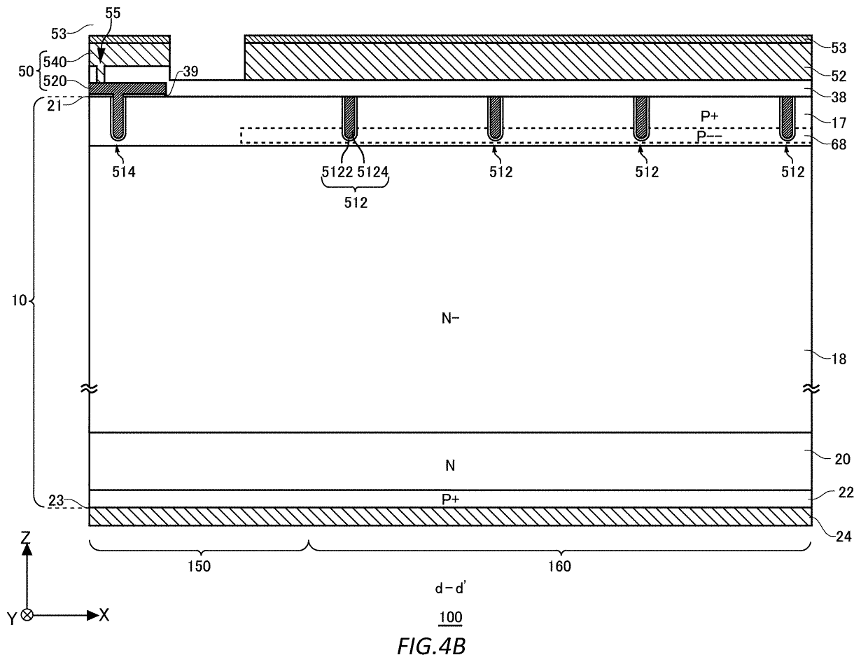

FIG. 4A shows an example of a diagram in which the trench bottom region 60 is projected to the upper surface of the region R in a variation of the semiconductor device 100. The semiconductor device 100 in this example differs from the example in FIG. 2 in that the trench bottom region 60 has a third trench bottom portion 68 provided in the transversal portion 160. This example describes points that differ from the example shown in FIG. 2 in particular, and other points may be the same as those of the example shown in FIG. 2.

The third trench bottom portion 68 may be provided to extend from one end of the second gate trench wiring portion 514 provided in the outer peripheral portion 150 of the semiconductor device 100 to the other end of the second gate trench wiring portion 514 provided in the outer peripheral portion 150. As described above, the region including the first active region 121, the second active region 122, the transversal portion 160, the outer peripheral portion 150 positioned in the +X axis direction of the active portion 120 may also have a similar configuration which has reflection symmetry with the region R. In other words, the third trench bottom portion 68 may be provided to extend to the region which has reflection symmetry.

The third trench bottom portion 68 in this example is provided to separate each of the second trench bottom region 64 provided in the first active region 121 and the second trench bottom region 64 provided in the second active region 122. The third trench bottom portion 68 may be provided to connect the second trench bottom region 64 provided in the first active region 121 to the second trench bottom region 64 provided in the second active region 122. In other words, the third trench bottom portion 68, the second trench bottom region 64 provided in the first active region 121, and the second trench bottom region 64 provided in the second active region 122 may be integrally provided.

FIG. 4B shows an example of the cross section d-d′ in the variation of the semiconductor device 100. The cross section d-d′ in this example is the cross section d-d′ in the semiconductor device 100 in FIG. 4A.

The third trench bottom portion 68 may be provided in contact with the bottom portion of the first gate trench wiring portion 512. The third trench bottom portion 68 may be provided in contact with the bottom portion of the second gate trench wiring portion 514. Therefore, the third trench bottom portion 68 may be provided in contact with the bottom portion of the intersection portion 510. The trench bottom region 60 being provided in contact with the bottom portion of the intersection portion 510 can relax the electric field strength in the bottom portion of the intersection portion 510. In this way, the decrease in withstand voltage of the semiconductor device 100 can be suppressed.

The third trench bottom portion 68 provided in contact with the bottom portion of the intersection portion 510 may be connected to the well region 17. The third trench bottom portion 68 in this example is connected to the well region 17 by being provided inside the well region 17. The third trench bottom portion 68 provided in contact with the bottom portion of the intersection portion 510 being connected to the well region 17 can keep the potential in the bottom portion of the intersection portion 510 at an emitter potential and can relax the electric field strength in the bottom portion of the intersection portion 510. In this way, the decrease in withstand voltage of the semiconductor device 100 can be suppressed.

The semiconductor device 100 in this example includes the third trench bottom portion 68 and the well region 17 below the intersection portion 510. The semiconductor device 100 may include only the third trench bottom portion 68 below the intersection portion 510.

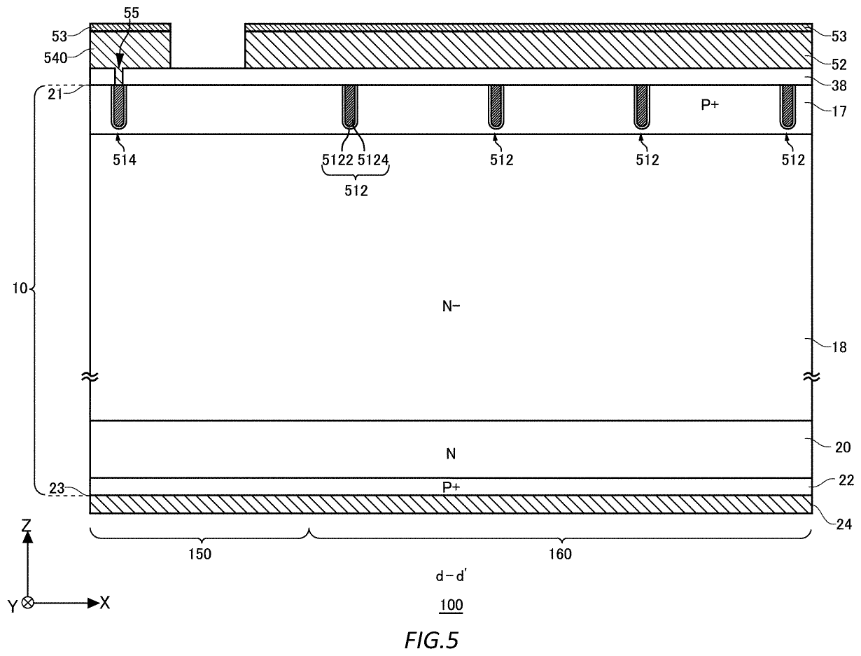

FIG. 5 shows an example of the cross section d-d′ in a variation of the semiconductor device 100. The semiconductor device 100 in this example differs from the example in FIG. 1F in that the gate wiring portion 50 does not have the gate runner 520. This example describes points that differ from the example shown in FIG. 1F in particular, and other points may be the same as those of the example shown in FIG. 1F.

The gate wiring portion 50 may be provided in the outer peripheral portion 150 of the semiconductor device 100 and have the gate metal layer 540 formed of metal. The gate metal layer 540 may be connected to the end portion of the second gate trench wiring portion 514 in the outer peripheral portion 150.

The gate wiring portion 50 in this example has the gate metal layer 540 and does not have the gate runner 520 in the outer peripheral portion 150 of the semiconductor device 100. Since the gate wiring portion 50 does not have the gate runner 520, polysilicon does not need to be left above the semiconductor substrate 10 in the manufacturing process of the semiconductor device 100, which allows entire surface etchback and can reduce the number of masks. In addition, polysilicon does not need to be left above the semiconductor substrate 10 in the manufacturing process of the semiconductor device 100, which allows the planarization of the semiconductor device 100 and can also improve the patterning precision in a large diameter wafer.

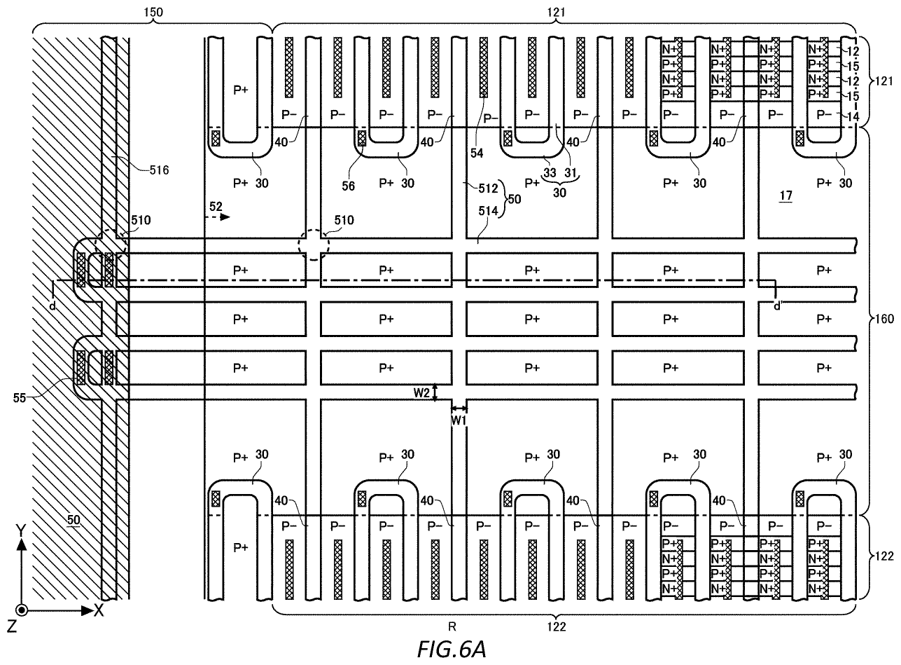

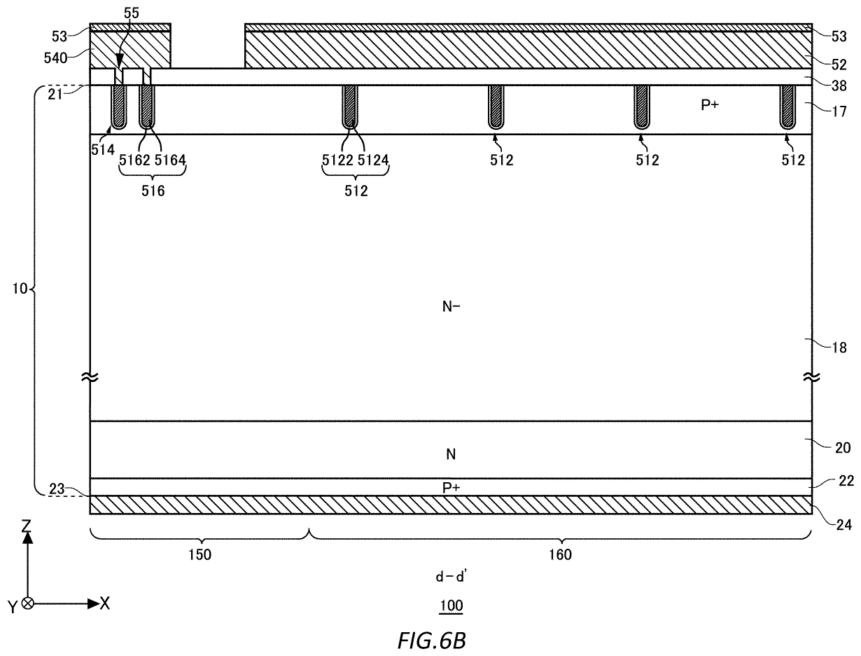

FIG. 6A shows an example of an enlarged view of the region R in a variation of the semiconductor device 100. The semiconductor device 100 in this example differs from the example in FIG. 1B in that the gate wiring portion 50 has the third gate trench wiring portion 516 provided in the outer peripheral portion 150 of the semiconductor device 100. This example describes points that differ from the example shown in FIG. 1B in particular, and other points may be the same as those of the example shown in FIG. 1B.

The third gate trench wiring portion 516 may be connected to the end portion of the second gate trench wiring portion 514 in the outer peripheral portion 150. The third gate trench wiring portion 516 may intersect the second gate trench wiring portion 514 at the intersection portion 510. The third gate trench wiring portion 516 may be provided to extend in the direction parallel to the end side 102.

FIG. 6B shows an example of the cross section d-d′ in the variation of the semiconductor device 100. The cross section d-d′ in this example is the cross section d-d′ in the semiconductor device 100 in FIG. 6A.

The third gate trench wiring portion 516 may have the same structure as the first gate trench wiring portion 512, the second gate trench wiring portion 514, the dummy trench portion 30, and the gate trench portion 40. The third gate trench wiring portion 516 has the gate trench, the gate dielectric film 5162, and the gate conductive portion 5164 formed on the side of the front surface 21. The gate dielectric film 5162 is formed to cover an inner wall of the gate trench. The gate conductive portion 5164 is formed inside the gate trench and is formed farther inward than the gate dielectric film 5162. The gate dielectric film 5162 insulates the gate conductive portion 5164 from the semiconductor substrate 10. The third gate trench wiring portion 516 may be covered with the interlayer dielectric film 38 on the front surface 21.

The intersection portion 510 may be provided inside the well region 17 in the cross section parallel to the depth direction of the semiconductor substrate 10 and the lower end may be shallower than the lower end of the well region 17. In other words, the diffusion depth of the well region 17 may be deeper than the depth of the second gate trench wiring portion 514 and the third gate trench wiring portion 516, and may be deeper than the depth of the intersection portion 510. The intersection portion 510 being provided inside the well region 17 can relax the electric field strength in the bottom portion of the intersection portion 510. In this way, the decrease in withstand voltage of the semiconductor device 100 can be suppressed.

The gate wiring portion 50 in this example has the gate metal layer 540 and the third gate trench wiring portion 516 and does not have the gate runner 520 in the outer peripheral portion 150 of the semiconductor device 100. Since the gate wiring portion 50 does not have the gate runner 520, polysilicon does not need to be left above the semiconductor substrate 10 in the manufacturing process of the semiconductor device 100, which allows entire surface etchback and can reduce the number of masks. In addition, polysilicon does not need to be left above the semiconductor substrate 10 in the manufacturing process of the semiconductor device 100, which allows the planarization of the semiconductor device 100 and can also improve the patterning precision in a large diameter wafer.

While the present invention has been described by way of the embodiments, the technical scope of the present invention is not limited to the above described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each process performed by an apparatus, system, program, and method shown in the claims, specification, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10 semiconductor substrate
12 emitter region
14 base region
15 contact region
16 accumulation region
17 well region
18 drift region
20 buffer region
21 front surface
22 collector region
23 back surface
24 collector electrode
30 dummy trench portion
31 extending portion
32 dummy dielectric film
33 connecting portion
34 dummy conductive portion
38 interlayer dielectric film
39 oxide film
40 gate trench portion
42 gate dielectric film
44 gate conductive portion
50 gate wiring portion
52 emitter electrode
53 plated film
54 contact hole
55 contact hole
56 contact hole
60 trench bottom region
62 first trench bottom portion
64 second trench bottom region
66 trench bottomless region
68 third trench bottom portion
100 semiconductor device
102 end side
112 gate pad
120 active portion
121 first active region
122 second active region
123 third active region
140 edge termination structure portion
150 outer peripheral portion
160 transversal portion
510 intersection portion
512 first gate trench wiring portion
514 second gate trench wiring portion
516 third gate trench wiring portion
520 gate runner
540 gate metal layer
5122 gate dielectric film
5124 gate conductive portion
5142 gate dielectric film
5144 gate conductive portion
5162 gate dielectric film
5164 gate conductive portion

What is claimed is:

1. A semiconductor device including an active portion, comprising:
a drift region of a first conductivity type provided in a semiconductor substrate;
a base region of a second conductivity type provided above the drift region;
a gate pad provided above the semiconductor substrate;
an emitter electrode provided above the semiconductor substrate;
a gate trench portion provided on a front surface of the semiconductor substrate in the active portion; and
a gate wiring portion for connecting the gate pad and the gate trench portion;
wherein the gate wiring portion has:
a first gate trench wiring portion which extends in a predetermined direction; and
a second gate trench wiring portion which extends in a different direction from the first gate trench wiring portion and intersects the first gate trench wiring portion at an intersection portion; and
the emitter electrode is provided above the intersection portion.

2. The semiconductor device according to claim 1, comprising a trench bottom region of the second conductivity type provided in contact with a bottom portion of the gate trench portion.

3. The semiconductor device according to claim 2, wherein a doping concentration of the trench bottom region is lower than a doping concentration of the base region.

4. The semiconductor device according to claim 2, wherein the trench bottom region is provided in contact with the bottom portion of the intersection portion.

5. The semiconductor device according to claim 4, comprising a well region of the second conductivity type provided above the drift region,
wherein the trench bottom region provided in contact with the bottom portion of the intersection portion is connected to the well region.

6. The semiconductor device according to claim 2, comprising a well region of the second conductivity type provided above the drift region,
wherein the trench bottom region is connected to the well region.

7. The semiconductor device according to claim 2, wherein the trench bottom region is provided to extend from one end of the second gate trench wiring portion provided in an outer peripheral portion of the semiconductor device to another end of the second gate trench wiring portion provided in the outer peripheral portion.

8. The semiconductor device according to claim 2, comprising a well region of the second conductivity type provided above the drift region,
wherein the trench bottom region has:
a first trench bottom portion; and
a second trench bottom region which is provided to be separated from the first trench bottom portion and is connected to the well region.

9. The semiconductor device according to claim 1, comprising a well region of the second conductivity type provided above the drift region,
wherein in a cross section parallel to a depth direction of the semiconductor substrate the intersection portion is provided inside the well region and has a lower end which is shallower than a lower end of the well region.

10. The semiconductor device according to claim 9, wherein the well region is provided to extend from one end of the second gate trench wiring portion provided in an outer peripheral portion of the semiconductor device to another end of the second gate trench wiring portion provided in the outer peripheral portion.

11. The semiconductor device according to claim 1, wherein the active portion has a first active region and a second active region, and
in a top view, the emitter electrode is provided from the first active region to the second active region over the second gate trench wiring portion.

12. The semiconductor device according to claim 1, wherein the active portion has a first active region and a second active region, and
the first gate trench wiring portion is provided to extend from the first active region to the second active region, and connects a gate trench portion of the first active region to a gate trench portion of the second active region.

13. The semiconductor device according to claim 1, wherein the second gate trench wiring portion includes a plurality of second gate trench wiring portions, and
the plurality of second gate trench wiring portions each has the intersection portion with the first gate trench wiring portion.

14. The semiconductor device according to claim 1, wherein a width of the second gate trench wiring portion is wider than a width of the first gate trench wiring portion.

15. The semiconductor device according to claim 1, wherein the gate wiring portion has a gate metal layer that is provided in an outer peripheral portion of the semiconductor device, is connected to an end portion of the second gate trench wiring portion in the outer peripheral portion, and is formed of metal.

16. The semiconductor device according to claim 2, wherein the gate wiring portion has a gate metal layer that is provided in an outer peripheral portion of the semiconductor device, is connected to an end portion of the second gate trench wiring portion in the outer peripheral portion, and is formed of metal.

17. The semiconductor device according to claim 1, wherein the gate wiring portion has a gate runner that is provided in an outer peripheral portion of the semiconductor device, is connected to an end portion of the second gate trench wiring portion in the outer peripheral portion, and is formed of polysilicon.

18. The semiconductor device according to claim 1, wherein the gate wiring portion has a third gate trench wiring portion that is provided in an outer peripheral portion of the semiconductor device and is connected to an end portion of the second gate trench wiring portion in the outer peripheral portion.

19. The semiconductor device according to claim 1, comprising a plated film provided on the emitter electrode above the intersection portion.

20. The semiconductor device according to claim 1, comprising an emitter region which is provided above the drift region and is of the first conductivity type with a higher doping concentration than that of the drift region,
wherein the emitter electrode is provided above the emitter region.
